(19) United States
(12) Patent Application Publication
(10) Pub. No.: US 2024/0357814 A1
(43) Pub. Date: Oct. 24, 2024

(54) NOR Memory Array, NOR Memory and Electronic Device

(71) Applicant: GIGADEVICE SEMICONDUCTOR INC., Beijing (CN)

(72) Inventors: Jun FENG, Beijing (CN); Tao XIONG, Beijing (CN); Linkai WANG, Beijing (CN)

(21) Appl. No.: 18/633,416

(22) Filed: Apr. 11, 2024

(30) Foreign Application Priority Data
Apr. 20, 2023 (CN) 202310429621.0

(51) Int. Cl. H10B 43/27; G11C 16/10; G11C 16/26; H10B 41/27; H10B 41/30; H10B 43/30

(52) U.S. Cl. CPC H10B 43/27; G11C 16/10; G11C 16/26; H10B 41/27; H10B 41/30; H10B 43/30; G11C 2216/02

(57) ABSTRACT

Disclosed are NOR memory array, NOR memory and electronic device. The NOR memory array comprises: multiple vertical memory groups arranged in n rows and m columns on a horizontal plane, one vertical memory group includes at least h vertically stacked memory transistors, where n, m, and h are natural numbers greater than 1, wherein, the memory transistors in one vertical memory group share a vertically extended columnar gate structure, part or all of columnar gate structures of vertical memory groups in a same row are connected to a same word line, part or all of memory transistors located at a same stack layer in vertical memory groups in a same column are connected to a same bit line, and an isolation part, for isolating active areas and bit lines of the memory transistors in the adjacent columns, is arranged between adjacent columns of the vertical memory groups.

### CROSS-REFERENCE TO RELATED APPLICATIONS

This application claims priority to Chinese patent application No. 202310429621.0 filed on Apr. 20, 2023, the disclosure of which is incorporated herein by reference in its entirety and for all purposes.

### TECHNICAL FIELD

The disclosure herein relates to the field of integrated circuits, and in particular, to a NOR memory.

### BACKGROUND

Currently, there are two common types of flash memory: NOR and NAND, where the former includes memory cells connected in parallel while the latter includes memory cells connected in series. Due to the difference in the circuit structure of memory cells, it is difficult to improve the integration density of memory cells in NOR memory compared to NAND memory.

Therefore, many new designs have been proposed to improve the integration density of memory cells in NOR memory.

### SUMMARY

According to some embodiments of the present disclosure, a NOR memory array is provided, comprising: multiple vertical memory groups arranged in n rows and m columns on a horizontal plane, wherein one vertical memory group includes at least h vertically stacked memory transistors, where n, m, and h are natural numbers greater than 1, wherein, the memory transistors in the one vertical memory group share a vertically extended columnar gate structure, part or all of the columnar gate structures of vertical memory groups in a same row are connected to a same word line, part or all of the memory transistors located at a same stack layer in vertical memory groups in a same column are connected to a same bit line, and an isolation part, for isolating active areas and bit lines of the memory transistors in the adjacent columns, is arranged between adjacent columns of the vertical memory groups.

According to some embodiments of the present disclosure, a NOR memory array is provided, comprising: multiple vertical memory groups arranged in n rows and m columns on a horizontal plane, wherein one vertical memory group includes at least h vertically stacked memory transistors, where n, m, and h are natural numbers greater than 1, wherein, the memory transistors in the one vertical memory group share a vertically extended columnar gate structure, part or all of the columnar gate structures of vertical memory groups in a same row are connected to a same word line, part or all of the memory transistors located at a same stack layer in vertical memory groups in a same column are connected to a same bit line, and wherein, at least one column of the vertical memory groups includes i sub-columns of the vertical memory groups, where i is a natural number greater than 1; wherein the columnar gate structures of at least two adjacent sub-columns of the vertical memory groups are spaced in the column direction.

According to some embodiments of the present disclosure, a NOR memory is provided, comprising a NOR memory array according to the above-described embodiments, and a write operation part, wherein, the write operation part is configured to apply a gate write voltage to a columnar gate structure of a vertical memory group to be written, and to apply a source voltage or a bit line write voltage to bit lines and source lines of the vertical memory group to be written, respectively, so that there is only a write voltage difference between two source/drain layers of a memory transistor in which data “0” is to be written.

According to some embodiments of the present disclosure, a NOR memory is provided, comprising a NOR memory array according to according to the above-described embodiments, and a read operation part, wherein, the read operation part is configured to apply a gate read voltage to a columnar gate structure of a vertical memory group to be read, and to apply a source voltage or a bit line read voltage to bit lines and source lines of the vertical memory group to be read, respectively, so that there is only a read voltage difference between two source/drain layers of one memory transistor to be read therein.

According to some embodiments of the present disclosure, an electronic device is provided, comprising a NOR memory array according to the above-described embodiments or a NOR memory according to the above-described embodiments.

### BRIEF DESCRIPTION OF FIGURES

The above and other objects, features and advantages of the present disclosure will become more apparent from the more detailed description of the exemplary embodiments of the present disclosure taken in conjunction with the accompanying drawings, wherein the same reference numerals generally refer to the same parts in exemplary embodiments of the present disclosure.

FIG. 1 shows a schematic plan view of a memory array in a NOR memory according to at least one embodiment of the present disclosure, FIG. 2 shows a schematic cross-sectional view taken along the dashed line A-A as shown in FIG. 1, and FIG. 3 shows a schematic cross-sectional view taken along the dashed line B-B as shown in FIG. 1.

FIG. 4 shows a circuit schematic diagram of a memory array in a NOR memory according to at least one embodiment of the present disclosure.

FIG. 5 shows a circuit schematic diagram of an exemplary write operation performed on a memory array therein by a NOR memory according to at least one embodiment of the present disclosure.

FIG. 6 shows a circuit schematic diagram of an exemplary write operation performed on a memory array therein by a NOR memory according to at least one embodiment of the present disclosure.

FIG. 7 shows a circuit schematic diagram of an exemplary read operation performed on a memory array therein by a NOR memory according to at least one embodiment of the present disclosure.

FIG. 8 shows a schematic plan view of a memory array in a NOR memory according to at least one embodiment of the present disclosure, FIG. 9 shows a schematic cross-sectional view taken along the dashed line A2-A2 in FIG. 8, and FIG. 10 shows a schematic cross-sectional view taken along the dashed line B2-B2 as shown in FIG. 8.

FIG. 11 shows a circuit schematic diagram of a memory array in a NOR memory according to at least one embodiment of the present disclosure.

FIG. 12 shows a schematic plan view of a memory array in a NOR memory according to at least one embodiment of the present disclosure.

FIG. 13 shows a schematic plan view of a memory array in a NOR memory according to at least one embodiment of the present disclosure, FIG. 14 shows a schematic cross-sectional view taken along the dashed line A3-A3 as shown in FIG. 13, and FIG. 15 shows a schematic cross-sectional view taken along the dashed line B3-B3 as shown in FIG. 13.

### DETAILED DESCRIPTION

Some embodiments of the present disclosure will be described in more detail below with reference to the accompanying drawings. Although the embodiments of the present disclosure are shown in the drawings, it should be understood that the present disclosure may be embodied in various forms and should not be limited to the embodiments set forth herein. Rather, these embodiments are provided so that this disclosure will be thorough and complete, and will fully convey the scope of the disclosure to those skilled in the art.

It is understood that, the terms “first” and “second” in this disclosure and the like are only used for descriptive purposes and would not be understood as indicating or implying relative importance or implying the quantity of technical features indicated. Therefore, the feature having the limitation of “first”, “second” or the like may explicitly or implicitly include one or more of the said features. In the description of this disclosure, the meaning of “multiple”, “a plurality of” or the like refers to two or more, unless otherwise specified.

In the description of this disclosure, it is noted that, unless otherwise specified and limited, the terms “install”, “mount”, “fit”, “connect”, “couple” or the like should be understood broadly; for example, it may refer to connecting fixedly or detachable or integrally; or it may refer to connecting mechanically or electrically, or communicating with each other; or it may refer to connecting directly, or connecting indirectly through an intermediate medium; or it may refer to communicating internally or interacting between two components. For those skilled in the art, the specific meanings of the above terms in this disclosure can be understood based on specific circumstances.

In addition, it is understood that, for the convenience of description, the dimensions of components shown in the attached drawings do not necessarily follow the actual proportional relationship. For example, the thickness or width of certain layers may be exaggerated relative to other layers. The techniques, methods, and devices known to those skilled in the relevant field may not be discussed in detail, but in the case of applying these techniques, methods, and devices, these techniques, methods, and devices should be considered as a part of this disclosure.

As mentioned before, in order to improve integration density of a memory array, this disclosure proposes a novel NOR memory array structure having a new three-dimensional arrangement. Detailed explanation of the novel structure and its beneficial effects in conjunction with the illustrated drawings are provided herein as examples of this disclosure. In this disclosure, a memory array refers to an array composed of memory cells, which is usually manufactured in a chip. Due to the large number of memory cells, improving the integration density of memory cells is the key to memory manufacturing. Usually, in addition to the memory array, the memory may also include peripheral circuits for reading/writing to the memory array, which may be manufactured in a chip same as or different from that including the memory array.

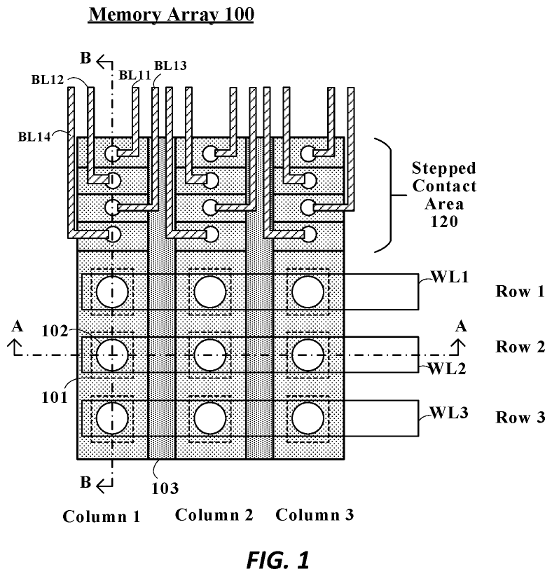

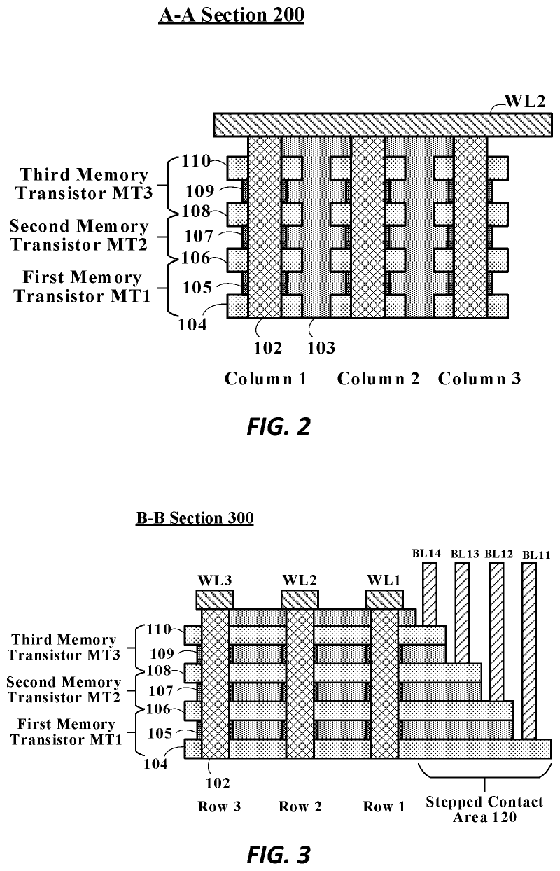

FIG. 1 shows a schematic plan view of a memory array in a NOR memory according to at least one embodiment of the present disclosure, FIG. 2 shows a schematic cross-sectional view taken along the dashed line A-A as shown in FIG. 1, and FIG. 3 shows a schematic cross-sectional view taken along the dashed line B-B as shown in FIG. 1.

In this disclosure, a memory array is typically manufactured on a substrate, with a horizontal plane referring to a surface parallel to the main surface of the substrate, and a vertical direction referring to a direction perpendicular to the main surface of the substrate. The plan view of FIG. 1 shows the arrangement of the memory array on the horizontal plane, while the cross-sectional views of FIGS. 2 and 3 show the stack structure of the memory array in the vertical direction. Please note that this disclosure does not have any limitations on the substrate used for manufacturing, which can be various substrates, such as a single crystal silicon wafer, a SOC substrate, etc., and in some cases, the substrate may be removed after finishing manufacturing the memory array. Therefore, for clarity, the substrate has been omitted in the accompanying drawings of this disclosure.

As shown in FIG. 1, the NOR memory array 100 includes multiple vertical memory groups 101 arranged in 3 rows×3 columns on the horizontal plane. Those skilled in the art may understand that the numbers of rows or columns in the disclosed drawings are only exemplary, and in practice, any n×m array may be made as needed, where n and m are natural numbers greater than 1. Those skilled in the art may understand that the n×m arrangement is only one of the ways to implement the technical solutions of the disclosed embodiments, and the embodiments of the present disclosure are not limited to this. In addition, the terms “n rows” or “m columns” mentioned in all embodiments of this disclosure only refer to the arrangement of multiple vertical memory groups 101 in an array, rather than limiting these vertical memory groups 101 to be exactly arranged in a neat array. That is to say, the “column” referred to throughout the embodiments of the present disclosure may be a completely virtual concept, which may refer to vertical memory groups 101 arranged in an approximately vertical direction, or even vertical memory groups 101 extended in an arc or curve shape, and which may be based on artificial partitioning. Similarly, the “row” referred to throughout the embodiments of the present disclosure may be a completely virtual concept, which may refer to vertical memory groups 101 arranged in an approximately vertical direction, or even vertical memory groups 101 extended in an arc or curve shape, and which may be based on artificial partitioning. The NOR memory array 100 referred to throughout the embodiments of the present disclosure includes the vertical memory groups 101 in the n×m array, which does not limit the number of vertical memory groups 101 contained in each row to be the same, and does not limit the number of vertical memory groups 101 contained in each column to be the same.

The structure shown in FIG. 1 includes three rows of vertical memory groups 101, and the number of vertical memory groups 101 included in each of the three rows is equal, that is, each row includes three vertical memory groups 101; but this is only an example and not a limitation on the scope of protection of the technical solution of the present disclosure. Those skilled in the art may understand that the number of vertical memory groups 101 included in each row can be the same or different. Similarly, the structure shown in FIG. 1 includes three columns of vertical memory groups 101, and the number of vertical memory groups 101 included in each of the three columns is equal, that is, each column includes three vertical memory groups 101; but this is only an example and not a limitation on the scope of protection of the technical solution of the present disclosure. Those skilled in the art may understand that the number of vertical memory groups 101 included in each column can be the same or different. Apparently, shown in FIG. 1 is a 3×3 array, i.e., n=3, m=3; but those skilled in the art may understand that n and m can be any number, which are not limited in the embodiments of the present disclosure. In this disclosure, a vertical memory group refers to a group of memory transistors stacked vertically, which may include h (h is a natural number greater than 1) memory transistors, and a memory transistor refers to a transistor having the function of storing data. In the plan view of FIG. 1, only a dashed box is used to roughly indicate the position of the vertical memory group 101, and this dashed box is not intended to represent any actual structure of the vertical memory group 101. Due to the stacking of multiple memory transistors in the vertical direction, i.e., multiple memory transistors occupying the footprint of only one memory transistor, the integration density of the memory array can be greatly improved.

In some embodiments, as shown in the cross-sectional views of FIGS. 2 and 3, each vertical memory group 101 may include three vertically stacked memory transistors (i.e., first to third memory transistors MT1-MT3). In one implementation, each memory transistor therein can be used as a memory cell to store 1 bit of information. As shown in FIGS. 2 and 3, exemplary examples are shown that each vertical memory group 101 includes three vertically stacked memory transistors; but this is only an example and not a limitation on the scope of protection of the technical solution of the present disclosure. Those skilled in the art can understand that the number of memory transistors included in each vertical memory group 101 can be the same or different. For example, one or more vertical memory groups 101 therein may include only 2 memory transistors (i.e., h=2 in some vertical memory groups 101), while other vertical memory groups 101 may include any number of memory transistors (e.g., h=3 in another vertical memory groups 101). For example, one or more vertical memory groups 101 therein may include four memory transistors (i.e., h=4 in some vertical memory groups 101), while other vertical memory groups 101 may include any number of memory transistors (e.g., h=3 in another vertical memory groups 101).

Specifically, as shown in FIGS. 2 and 3, an vertical memory group 101 includes source/drain layers and channel layers alternately stacked in the vertical direction, which are a first source/drain layer 104, a first channel layer 105, a second source/drain layer 106, a second channel layer 107, a third source/drain layer 108, a third channel layer 109, and a fourth source/drain layer 110 disposed from bottom to top. In some possible implementations, these source/drain layers and channel layers are arranged along the direction of the vertically extended columnar gate structure 102 shared by the vertical memory group 101, forming three memory transistors arranged in the vertical direction (i.e., their source-drain currents flow in the vertical direction). In some possible implementations, these source/drain layers and channel layers surround the vertically extended columnar gate structure 102 shared by the vertical memory group 101, and are arranged along the direction in which the columnar gate structure 102 extends.

As shown in FIGS. 2 and 3, the first memory transistor MT1 includes the first source/drain layer 104, the first channel layer 105, and the second source/drain layer 106; the second memory transistor MT2 includes the second source/drain layer 106, the second channel layer 107, and the third source/drain layer 108; while the third memory transistor MT3 includes the third source/drain layer 108, the third channel layer 109, and the fourth source/drain layer 110. That is to say, the two adjacent memory transistors in the vertical direction share one source/drain layer; i.e., there is one source/drain area that is connected therebetween.

For example, the alternately stacked source/drain layers and channel layers in the vertical memory group 101 may be formed by epitaxially growing monocrystalline silicon on the substrate. The epitaxial growth can effectively control the thickness of each layer, especially the channel layer (equivalent to the channel length of the memory transistor). Moreover, in-situ doping may be carried out during the epitaxial growth to achieve the required doping polarity and concentration for each source/drain layer and channel layer. In this case, in some possible implementations, these alternately stacked source/drain layers and channel layers in the finally formed devices may actually be composed of the same material (i.e., monocrystalline silicon), which may be distinguished by their doping concentrations. In addition, in the examples shown in FIGS. 2 and 3, the channel layer of each memory transistor is fabricated to have a width different from its source/drain layers in the horizontal direction, thus the channel layer and the source/drain layers can also be distinguished from each other based on their shapes. This disclosure is not limited to this, but may be achieved through various processes, and the channel layer may also have the same shape as the source/drain layers.

In addition, in the examples shown in FIGS. 1 and 3, three vertical memory groups in the same column share these four source/drain layers, namely the first source/drain layer 104, the second source/drain layer 106, the third source/drain layer 108, and the fourth source/drain layer 110; that is to say, there are (h+1) source/drain layers in the same column, these (h+1) source/drain layers respectively extend along the direction of the column, and all memory transistors in this column use these (h+1) source/drain layers as their own source/drain layers. As shown in FIGS. 1 and 3, the source/drain layers of all memory transistors located at the same layer in the vertical direction are continuous. Therefore, only one contact may be used to achieve the electrical connection to the source/drain regions of all memory transistors at the same layer (also referred as the same stack layer) in the same column, which further improves the integration density. The same layer may refer to, as shown in FIG. 2, the memory transistors at the bottom of the first, second, and third columns, which are referred to as the same layer; correspondingly, the memory transistors at the top of the first, second, and third columns are also referred to as the same layer; the memory transistors in the middle of the first, second, and third columns are also referred to as the same layer. For example, as shown in FIGS. 1 and 3, a stepped contact area 120 may be fabricated at the end of each column, where the stepped contact area 120 is provided with contacts for connecting the respective source/drain layers. The contacts are used to respectively lead out and electrically connect these four source/drain layers to four metal lines (i.e., Bit Lines, abbreviated as BLs) BL11-BL14, respectively. Due to the fact that the source/drain regions at the upper and lower ends of the memory transistor are structurally identical, each of the source/drain regions at both ends of the memory transistor may serve as a source region or a drain region. Therefore, each of the bit lines BL11-BL14 may also serve as a bit line (BL) or a source line (SL) of the memory transistor. In addition, every adjacent two memory transistors share a bit line, therefore, in some implementations, the bit line/source line of one of the memory transistors may simultaneously serve as the bit line/source line of the adjacent memory transistors. That is to say, the bit lines and source lines of the respective memory transistors are not fixed, but are determined based on voltages applied separately during an operation. For the sake of simplicity and convenience in this disclosure, there is no distinction between bit lines and source lines in the attached drawings. Instead, all metal lines connected to the source/drain regions are collectively referred to as bit lines BLs. In practical use, each of the bit lines (e.g., BL11-BL14) in any of FIGS. 1-3 may be used as the source line or the bit line. That is, when the bit line in any of FIGS. 1-3 is applied with the source voltage required for the memory transistor, the corresponding metal line serves as the source line of the memory transistor, and at this time, the metal line may be referred to as the source line. When the bit line in any of FIGS. 1-3 is applied with the drain voltage required for the memory transistor, the corresponding metal line serves as the bit line of the memory transistor, and at this time, the metal line may be referred to as the bit line.

The method of performing read or write operation on the memory transistors may refer to the explanation of embodiments introduced later.

In the examples shown in FIGS. 1 and 3, all h memory transistors in the same column share this (h+1) source/drain layers. Those skilled in the art may understand that some memory transistors in the same column may share part of the source/drain layers, while some other memory transistors may share other source/drain layers or have independent source/drain layers. Correspondingly, the contacts may also be set based on the structure of the source/drain layers, and will not be repeated here.

Please note that in order to make the illustrations clear and highlight the key points, there are blank areas left between many components in the cross-sectional views of FIGS. 2 and 3, which does not necessarily limit these areas to be empty. In some implementations, in actual devices, all or part of these blank areas may be filled with electrical insulation materials to isolate and support these components.

In addition, although only one circle is used in the drawings to represent the columnar gate structure 102 used as the gate for all memory transistors in the same vertical memory group, the columnar gate structure 102 may be composed of multiple layers, which at least includes a functional layer for storing information and a conductive layer for applying voltage. For example, in some embodiments, the columnar gate structure 102 may sequentially include an oxide layer, a charge capture layer, an isolation layer, and a gate metal layer from the outside to the inside. Those skilled in the art understand that the columnar gate structure 102 is not limited to this, but may be set accordingly according to the type of memory transistor. In FIGS. 1-3, the cross-section of the columnar gate structure 102 may be circular, i.e., the columnar gate structure 102 is cylindrical; but this is just an example. In the embodiments of the present disclosure, there is no limitation on this, and the cross-section of the columnar gate structure 102 may be of any shape.

FIGS. 2 and 3 only serve as examples to illustrate the case where a vertical memory group includes three stacked memory transistors, but more memory transistors may be stacked as needed. In the case where a vertical memory group includes h (h is a natural number greater than 1) memory transistors stacked vertically, the vertical memory group may include (h+1) source/drain layers and h channel layers alternately stacked in the vertical direction, wherein each channel layer and two source/drain layers contacted therewith in the vertical direction collectively form one memory transistor, and the (h+1) source/drain layers are respectively connected to (h+1) metal lines. In some examples, the (h+1) metal lines may serve as the respective bit lines or source lines of the h memory transistors. In some implementations, two adjacent memory transistors in the vertical direction share a common source/drain layer.

In some possible implementations, as mentioned before, all vertical memory groups in the same column share the (h+1) source/drain layers, and contacts for respectively leading out and connecting the (h+1) source/drain layers to the (h+1) metal lines are provided at end of each column. That is, each of the aforementioned (h+1) source/drain layers runs through the vertical memory groups in the same layer in a direction perpendicular or approximately perpendicular to the columnar gate structure 102. As shown in FIGS. 1 to 3, all memory transistors in this column share this (h+1) source/drain layers.

Those skilled in the art understand that the vertical memory group disclosed in this disclosure is not limited to the specific structure described in combination with FIGS. 2 and 3. For example, in some cases, each memory transistor may store more than 1 bit of information, or in some cases, an isolation layer may be set between adjacent memory transistors in the vertical direction, so as to lead out a separate bit line for each memory transistor connected in parallel to the same word line (WL), like a conventional NOR memory array. However, compared to the structure of setting the isolation layer, the vertical memory group according to FIGS. 2 and 3 of the present disclosure has a simpler structure, is easier to manufacture, and reduces the number of required bit lines and source lines, thereby further improving the integration density.

In addition, as shown in FIGS. 1-3, the columnar gate structures 102 of all vertical memory groups in the same row are connected to the same word line WL1, WL2, or WL3, while the memory transistors located at the same stack layer in all vertical memory groups in the same column share the same bit line as mentioned earlier. In addition, an isolation part 103 is arranged between adjacent columns of the vertical memory groups, to isolate the active areas and bit lines of the memory transistors in different columns. As an example, the active area may include source/drain layers and a channel layer. Therefore, according to the memory array structure disclosed in this disclosure, it is possible to uniquely locate a memory cell solely through its word line and its bit line, and one memory cell therein is one memory transistor. Therefore, the architecture of the memory array according to this disclosure is simple, greatly reducing design difficulty, and improving manufacturability. Moreover, due to the presence of isolation parts between the bit lines of different columns, the leakage and crosstalk on the bit lines are reduced.

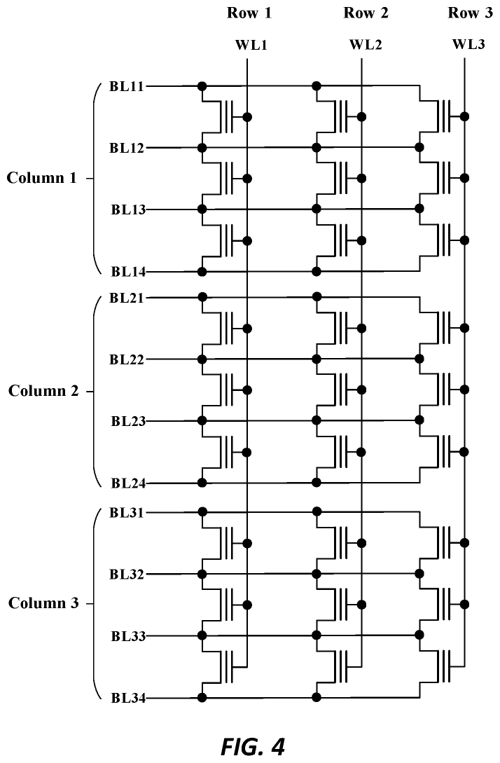

The following is a detailed description of the circuit structure and corresponding read/write operations of the memory array shown in FIGS. 1-3, combined with FIGS. 4-7.

FIG. 4 shows a schematic circuit diagram of the memory array shown in FIGS. 1-3.

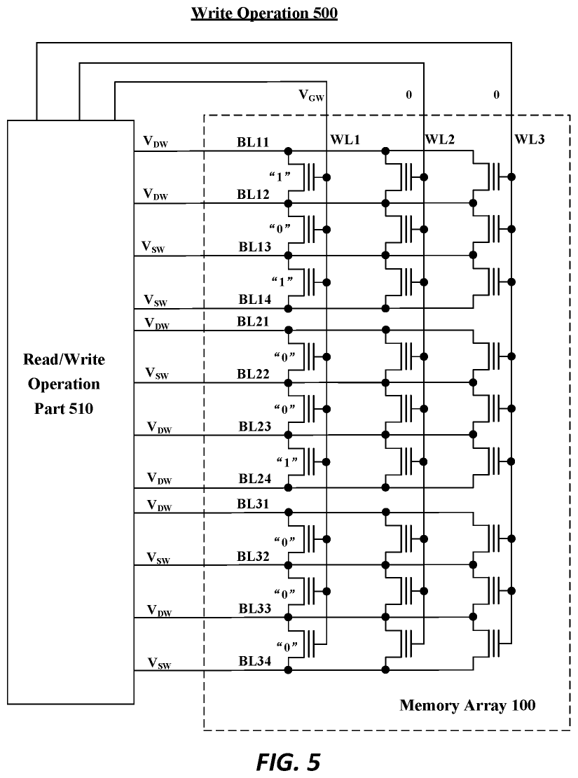

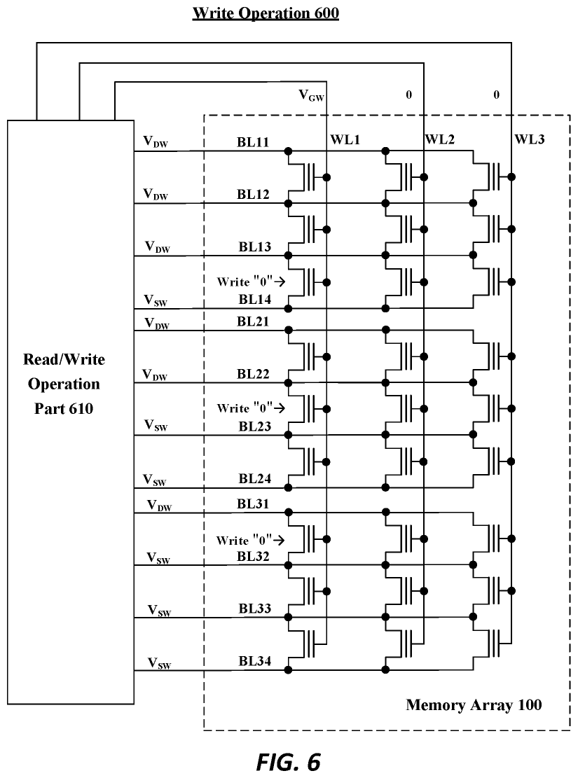

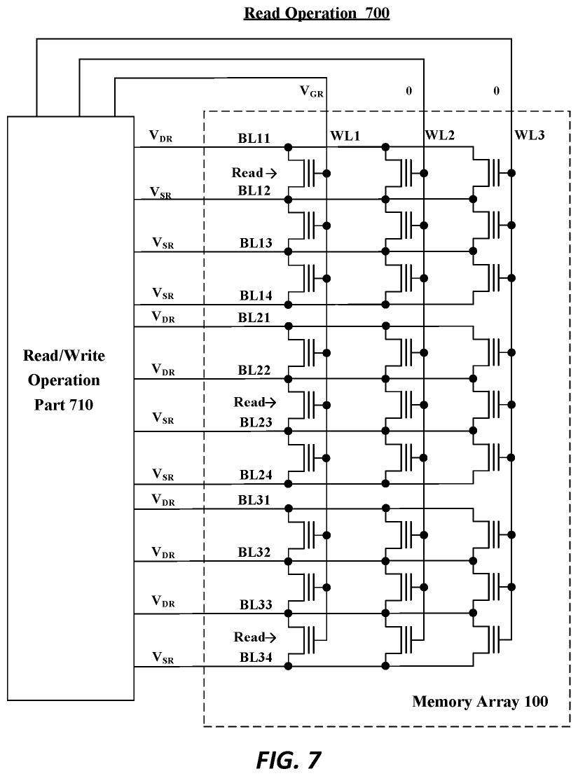

As shown in FIG. 4, the gates of the memory transistors in the same row are all connected to the same word line WL1, WL2, or WL3, while all memory transistors in the same column share the respective common bit lines BL11-BL14, BL21-BL24, or BL31-BL34. As mentioned before, the bit lines in the embodiments of the present disclosure may also serve as the source lines. As mentioned before, since the memory array disclosed in this disclosure is arranged in a three-dimensional manner, each vertical memory group in each column includes three vertically stacked memory transistors. Therefore, as shown in FIG. 4, each column may actually include three sub-columns arranged in the vertical direction, and the memory transistors in adjacent sub-columns in the vertical direction share a source/drain region. The circuit structure shown in FIG. 4 is only an example, and the embodiments of the present disclosure do not limit the write operation of FIG. 5 or FIG. 6 and the read operation of FIG. 7 can only be applied to the circuit structure shown in FIG. 4.

FIG. 5 shows an example of a write operation performed on the memory array shown in FIG. 4 by a NOR memory according to at least one embodiment of the present disclosure. FIG. 6 shows another example of a write operation performed on the memory array shown in FIG. 4 by a NOR memory according to at least one embodiment of the present disclosure. FIG. 7 shows an example of a read operation performed on the memory array shown in FIG. 4 by a NOR memory according to at least one embodiment of the present disclosure. The write operation example shown in FIG. 5 or FIG. 6 and the read operation example shown in FIG. 7 may be implemented separately or in combination, and may also be implemented independently or in combination with one or more other embodiments of the present disclosure. The embodiments of the present disclosure do not limit this. In the subsequent exemplary explanation, the implementation of the write operation in FIG. 5 or FIG. 6 and the implementation of the read operation shown in FIG. 7 are combined for exemplary explanation. However, those skilled in the art may understand that this exemplary explanation is not a limitation of the embodiments of the present disclosure. The read/write operation part 510, 610, or 710 may only implement the write operation shown in FIG. 5 or FIG. 6, or only implement the read operation shown in FIG. 7.

It is noted that in all embodiments of the present disclosure, the structures of the read/write operation parts 510, 610, and 710 may be the same or different. Although it is called a read/write operation part, it may be used to perform only a read operation, only a write operation, or both read and write operations.

The following is an example of using a read/write operation part 510, 610, or 710 to illustrate the write and read operations on the circuit diagram shown in FIG. 4. As shown in FIGS. 5, 6, and 7, the NOR memory according to the embodiment of the present disclosure may also include a read/write operation part 510, 610, or 710 in addition to the above-described memory array 100, for applying corresponding read/write voltages to the respective word lines and bit lines of the memory array 100 to achieve read/write operations. Although FIGS. 5, 6, and 7 illustrate the implementation of read/write operations by the same operation part 510, 610, or 710, the present disclosure is not limited to this. In some embodiments, separate read operation part and write operation part may also be used to implement read operation and write operation respectively, or in some embodiments, different write operation parts may also be used to implement the two exemplary write operations of FIGS. 5 and 6 respectively. In addition, those skilled in the art may understand that there are various circuit implementations to achieve the read/write operations detailed later. In addition, in some embodiments, an erase operation is required before performing a write operation on the memory array. Although not shown in the drawings, those skilled in the art may understand that the read/write operation part 510, 610, or 710 may also erase the memory transistors in the memory array 100 in various ways. For example, in some embodiments, a gate voltage and a drain voltage required for erasure may be applied simultaneously to all word lines and all bit lines in the memory array 100, thereby achieving erasure of all memory transistors simultaneously. Please note that in this disclosure, the memory transistor that has undergone erasure processing is considered as storing data “1”, while the memory transistor that has undergone write processing is considered as storing data “0”. That is to say, during the write operation, there is actually no need to perform any write operations on the memory transistor in which data “1” is to be written.

FIG. 5 shows an exemplary write operation 500 for simultaneously writing all memory transistors that share the same word line WL1. FIG. 5 labels “0” or “1” next to each memory transistor to indicate the data to be written in the corresponding memory transistor. As shown in FIG. 5, the word line to be written (and all columnar gate structures connected to this word line) is applied with a gate write voltage Vow, while the remaining word lines are applied with 0V voltage. Please note that the 0V voltage is only an example, and in some embodiments, other gate voltages that do not affect the write operation may also be applied to replace the 0V voltage. Regardless of the implementation used, all embodiments of this disclosure do not limit the magnitudes of the gate write voltage Vow and the gate voltage of the remaining word lines mentioned above, as long as the gate write voltage Vow is greater than the gate voltage threshold value used for the write operation, and the gate voltage of the remaining word lines mentioned above is less than the gate voltage threshold value used for the write operation. In addition, the 12 bit lines BL11-BL14, BL21-BL24, and BL31-BL34 of the three vertical memory groups to be written connected to the same word line WL1 are respectively applied with either a source voltage V_{SW} or a bit line write voltage V_{DW}. From FIG. 5, it can be seen that, during the write operation, the four bit lines of the same vertical memory group are applied voltages to create a write voltage difference (V_{DW}−V_{SW}) between the two source/drain regions of the memory transistor to be written data “0”, while there is no write voltage difference between the two source/drain regions of the memory transistor to be written data “1”. That is to say, all embodiments of this disclosure do not limit the magnitudes of the aforementioned source voltage V_{SW} and the aforementioned bit line write voltage V_{DW}, as long as the voltage difference (V_{DW}−V_{SW}) between the two is greater than the drain-source voltage (VDs) threshold value used for the write operation. All embodiments of this disclosure do not limit the magnitudes of the voltages respectively applied to the two source/drain regions of the memory transistor to be written data “1”, as long as the drain-source voltage is less than the drain-source voltage threshold value used for the write operation (i.e., there will be no sufficient current flow to achieve writing, thus no write processing will occur). The exemplary voltage difference between the two source/drain regions of the memory transistor to be written data “1” may be 0V or close to 0V. The write operation of this disclosure is not limited to this, but may apply appropriate voltage sequences to respective word lines and bit lines based on the type of memory transistor or other requirements. The opposite approach may also be adopted, where, during the write operation, there is a write voltage difference (V_{DW}−V_{SW}) greater than the threshold value between the two source/drain regions of the memory transistor to be written data “1”, while there is no write voltage difference greater than the threshold value between the two source/drain regions of the memory transistor to be written data “0”.

FIG. 6 shows another exemplary write operation 600 on the circuit diagram shown in FIG. 4, which differs from the write operation 500 in FIG. 5 in that only one memory transistor in the vertical memory group is written at a time, rather than all memory transistors. FIG. 6 indicates “write ‘0’” next to the memory transistor to be written in each vertical memory group. As shown in FIG. 6, the word line to be written (and all columnar gate structures connected to this word line) is applied with a gate write voltage Vow, while the remaining word lines are applied with 0V voltage. Please note that the 0V voltage is only an example, and in some embodiments, other gate voltages that do not affect the write operation may also be applied instead of the 0V voltage. In addition, the 12 bit lines BL11-BL14, BL21-BL24, and BL31-BL34 of the three vertical memory groups to be written connected to the same word line WL1 are respectively applied with either a source voltage V_{SW} or a bit line write voltage V_{DW}. From FIG. 6, it can be seen that for the same vertical memory group, the source voltage V_{SW} is applied to the source of the memory transistor to be written and all bit lines on the same side as this source (i.e., opposite to its drain), while the bit line write voltage Vow is applied to the drain of the memory transistor to be written and all bit lines on the same side as this drain (i.e., opposite to its source). In other words, during the write operation, the four bit lines of the same vertical memory group are applied with voltages such that there is a write voltage difference (V_{DW}−V_{SW}) between the two source/drain regions of only the memory transistor where data “0” is to be written, while there is no write voltage difference between the two source/drain regions of the other memory transistors so that there is no current flow sufficient. The write operation of this disclosure is not limited to this, but may apply appropriate voltage sequences to respective word lines and bit lines based on the type of memory transistor or other requirements. The opposite approach may also be adopted, where, during the write operation, the four bit lines of the same vertical memory group are applied with voltages such that there is a write voltage difference (V_{DW}−V_{SW}) between the two source/drain regions of only the memory transistor where data “1” is to be written, while there is no write voltage difference between the two source/drain regions of the other memory transistors where data “0” is to be written.

FIG. 7 shows an exemplary read operation 700 for reading one memory transistor from all vertical memory groups that share the same word line WL1. FIG. 7 labels “read” next to the memory transistor to be read. As shown in FIG. 7, the word line to be read (and all columnar gate structures connected to this word line) is applied with a gate read voltage VGR, while the remaining word lines are applied with 0V voltage. Please note that the 0V voltage is only an example, and in some embodiments, other gate voltages that do not affect the read operation may also be applied instead of the 0V voltage. In addition, the 12 bit lines BL11-BL14, BL21-BL24, and BL31-BL34 of the three vertical memory groups to be read connected to the same word line WL1 are respectively applied with either a source voltage V_{SR} or a bit line read voltage V_{DR}. From FIG. 7, it can be seen that for the same vertical memory group, the source voltage V_{SR} is applied to the source of the memory transistor to be read and all bit lines on the same side as this source (i.e., the side opposite to its drain), while the bit line read voltage V_{DR} is applied to the drain of the memory transistor to be read and all bit lines on the same side as this drain (i.e., the side opposite to its source). In other words, the four bit lines of the same vertical memory group are applied with voltages such that there is a read voltage difference (V_{DR}−V_{SR}) between the two source/drain layers of only the memory transistor to be read so as to achieve read processing, while there is no read voltage difference between the two source/drain layers of the other memory transistors, so there is no current flow sufficient to achieve reading and it does not affect read processing. The read operation of this disclosure is not limited to this, but may apply appropriate voltage sequences to respective word lines and bit lines based on the type of memory transistor or other requirements.

By utilizing the write operation 500 or 600 shown in FIG. 5 or FIG. 6, and/or the read operation 700 shown in FIG. 7 as described above, it is possible to easily and quickly implement write and/or read operations for the memory array 100.

In some embodiments, although smaller size processes can be used to produce memory arrays, the size of the columnar gate structure 102 (such as the diameter of the gate circular hole) cannot be further reduced. For example, in some embodiments, the minimum size (including its width (diameter of the circular hole) and spacing) of the columnar gate structure may reach around 100 nm and cannot be further reduced, while smaller size processes (such as 40 nm or 28 nm process) can be used to fabricate memory arrays. In other words, the minimum size (including its width and spacing) of the metal line (word line WL) connecting the columnar gate structures can reach around 40 nm or 28 nm.

Therefore, in order to arrange the memory array more closely and further improve the array density, part of the columnar gate structures in one column in FIG. 1 may be moved a certain distance in the row direction, so as to be spaced from adjacent columnar gate structures at certain spacings in both the column and row directions. That is, the spacing between adjacent columnar gate structures is a slanted distance, thereby reducing the spacings in the column and/or row directions so as to further reduce the vertical and/or horizontal dimensions of the entire memory array. For example, at least one column of the vertical memory groups may include i sub-columns of the vertical memory groups, where i is a natural number greater than 1; wherein the columnar gate structures of at least two adjacent sub-columns of the vertical memory groups are spaced in the column direction. That is to say, the columnar gate structures of adjacent vertical memory groups in the row direction do not completely overlap in the column direction as shown in FIG. 1, but are staggered by a certain distance. In addition, the isolation part 103 between adjacent columns in the memory array 100 shown in FIG. 1 may be removed, thereby further reducing the horizontal size of the memory array. That is to say, an improved arrangement of memory arrays may be proposed, which can reduce the area occupied by the entire memory array in the horizontal plane and further increase the array density. Below, this improved implementation will be presented more clearly in conjunction with the attached drawings.

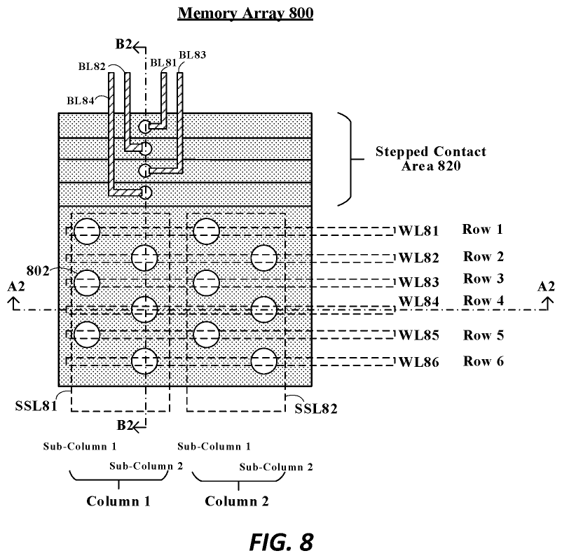

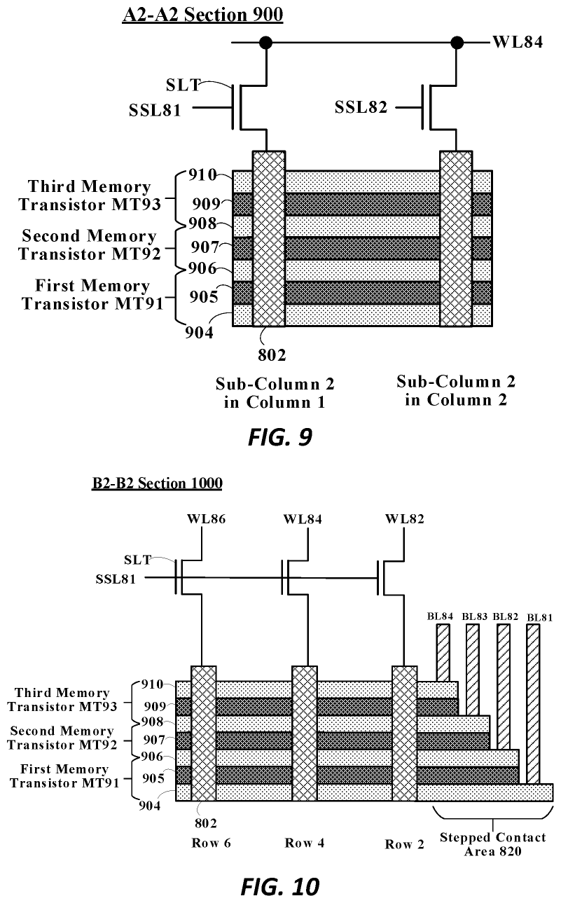

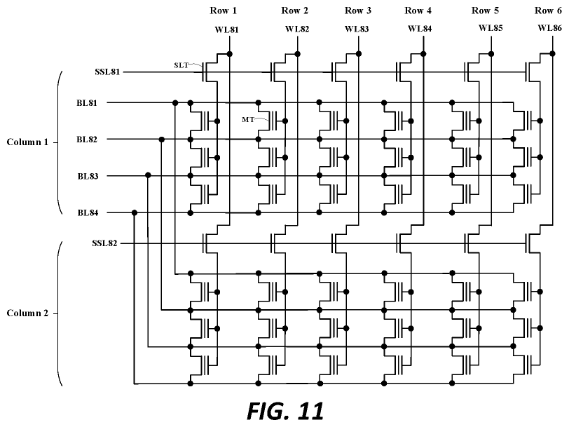

FIG. 8 shows a schematic plan view of a memory array in a NOR memory according to at least one embodiment of the present disclosure, FIG. 9 shows a schematic cross-sectional view taken along the dashed line A2-A2 as shown in FIG. 8, FIG. 10 shows a schematic cross-sectional view taken along the dashed line B2-B2 as shown in FIG. 8, and FIG. 11 shows a circuit schematic diagram of the memory array shown in FIGS. 8-10.

As shown in FIG. 8, the NOR memory array 800 includes multiple vertical memory groups arranged in 6 rows×2 columns on the horizontal plane, where the position of each vertical memory group is indicated by the columnar gate structure 802 shared by each vertical memory group in the figure. Those skilled in the art may understand that, as previously described with FIG. 1, the numbers of rows and columns, as well as the number of vertical memory groups included in each row/column, in the disclosed drawings are only exemplary, and in practice, any n×m array may be made as needed, where n and m are natural numbers greater than 1, and the number of vertical memory groups included in each row/column may also be changed as needed. In addition, although FIGS. 9 and 10 illustrate the structure of vertical memory groups similar to FIGS. 2 and 3, those skilled in the art may understand that, as previously described with FIGS. 1-3, the number of memory transistors contained in each vertical memory group and the vertically stacked structure as shown in the present disclosure are only exemplary, and in practice, any number of memory transistors may be included as needed, and vertical memory groups may be fabricated with any stacking structure as needed. Each memory transistor may store 1 bit of information, or more than 1 bit of information.

In addition, due to the fact that the memory array 800 in FIG. 8 does not have isolation parts between adjacent columns as shown in FIG. 1, there is no isolation between the active areas of the memory transistors at respective stack layers in the respective vertical memory groups in the columns, and it is not possible to apply a bit line voltage or a source line voltage separately to the memory transistors in each column. Therefore, as shown in FIGS. 8-11, all columns in the memory array 800 share four bit lines BL81-BL84 led out in the stepped contact area 820. Therefore, the memory array 800 cannot uniquely locate one vertical memory group solely through its bit line and word line as shown in FIG. 1. Therefore, in some possible implementations, as shown in the cross-sectional diagrams of FIGS. 9 and 10, as well as the circuit diagram of FIG. 11, the columnar gate structures of the respective vertical memory groups are not directly connected to the respective word lines, but are connected to the respective word lines through respective selection transistors SLT. One of source/drain electrodes of each selection transistor SLT is connected to the cylindrical gate of its corresponding vertical memory group, while the other source/drain electrode is connected to the word line WL of the row to which the vertical memory group belongs, and its gate electrode is connected to a selection line SSL of the column to which the vertical memory group belongs. As shown in the circuit diagram of FIG. 11, the gates of the selection transistors of the vertical memory groups in the same column are all connected to the same selection line SSL81 or SSL82; and in some implementations, the voltage on the selection line of the selected column may be made high, so that the selection transistors of that column are all turned on, thereby conducting the voltages on the word lines of all rows to the gates of the vertical memory groups of all rows, while the voltage on the selection line of the unselected column is low voltage that fails to turn on the selection transistor, so that the unselected column cannot receive the voltages applied on the word lines.

In the schematic plan view shown in FIG. 8, dashed boxes are used to represent the word lines WL81-WL86 for respective rows and the selection lines SSL81-SSL82 for respective columns. By using the word lines and selection lines, one vertical memory group at the overlap of one word line and one selection line may be uniquely selected. In some possible implementations, each selection transistor SLT may have the same structure as ordinary MOS transistors. The selection transistors may be fabricated on a chip same as or different from that of the memory array 800. For example, the selection transistors may be directly fabricated above the upper surfaces of the columnar gate structures of the respective vertical memory groups, or may be fabricated in the peripheral area around the memory array 800 in the same chip, or may be fabricated on another chip and connected to the columnar gate structures of the respective vertical memory groups in various ways. The word lines and selection transistors SLT may be fabricated in various structural ways in various regions, without necessarily being fabricated above the memory array 800. Therefore, in the cross-sectional diagrams of FIGS. 9 and 10, the part including the word lines and the selection transistors is represented by circuit symbols instead of cross-sectional diagrams.

As shown in FIG. 8, in some embodiments, two or more adjacent sub-columns may be set in one column, and each sub-column may include two or more columnar gate structures; among them, the columnar gate structures of adjacent sub-columns are staggered in the row direction. Although FIG. 8 exemplify the structure of one column including two sub-columns, those skilled in the art may understand that this exemplary explanation is not a limitation to the embodiments of the present disclosure; on the basis of ensuring the possibility of technological implementation, any number of sub-columns may be arranged in one column; for example, three or more sub-columns may be arranged in one column (not shown in the accompanying drawings of the specification).

The construction of the columnar gate structure 802 shown in FIG. 8 may refer to the accompanying drawings of other embodiments of the present disclosure, such as the columnar gate structure 102 shown in FIGS. 1-3, or may be any other shape or structure of the columnar gate structure. In some implementations, in order to arrange the memory array more closely, each columnar gate structure 802 in the two sub-columns in FIG. 8 may have the same distance from each of its adjacent columnar gate structures 802 in the column direction, and for example, this distance may be the minimum column spacing for the process or design. In some implementations, each columnar gate structure 802 in the two sub-columns in FIG. 8 may have the same distance from each of its adjacent columnar gate structures 802 in the row direction, and for example, this distance may be the minimum row spacing for the process or design. In the above embodiments, the minimum row spacing may be same as or different from the minimum column spacing. In some possible implementations, in order to arrange the memory array more closely, each columnar gate structure 802 may have the same distance (such as minimum spacing) from each of its adjacent columnar gate structures 802 in the column or row direction. That is to say, the columnar gate structure 802 may be arranged most compactly in a hexagonal pattern to further enhance array density. In addition, although only one contact for connecting a source/drain layer is shown in the stepped contact area 820 in the accompanying drawings of the present disclosure, the present disclosure is not limited to this. For example, in some embodiments, multiple contacts in contact with the same source/drain layer may be formed as needed and connected together with a metal line. The aforementioned implementation methods for contacts and hexagonal pattern arrangement may be implemented independently or combined, and the embodiments of the present disclosure do not limit this.

In some embodiments, as shown in the cross-sectional views of FIGS. 9 and 10, each vertical memory group in the memory array 800 may include three vertically stacked memory transistors (i.e., the first to third memory transistors MT91-MT93), whose main difference from the structure of the vertical memory groups shown in the cross-sectional views of FIGS. 2 and 3 is that, there is no isolation between adjacent columns, and there is also no isolation between the channels of adjacent memory transistors at the same stack layer. Other specific constructions and manufacturing processes may refer to those in the embodiments described in combination with FIGS. 2 and 3, and will not be further elaborated here. Those skilled in the art understand that the present disclosure is not limited to the construction and manufacturing process of the vertical memory group mentioned above, and vertical memory groups with any other construction and manufacturing process may also be used.

Please note that in order to make the illustrations clear and highlight the key points, there are blank areas left between many components in the cross-sectional views of FIGS. 9 and 10, which does not necessarily limit these areas to be empty. In some implementations, in actual devices, all or part of these blank areas may be filled with electrical insulation materials to isolate and support these components.

The write/read operations of the memory array 800 shown in FIGS. 8-10 may refer to the content of the write/read operations described earlier in conjunction with FIGS. 5-7, but other suitable write/read operations may also be used, and thus those operations will not be repeated here.

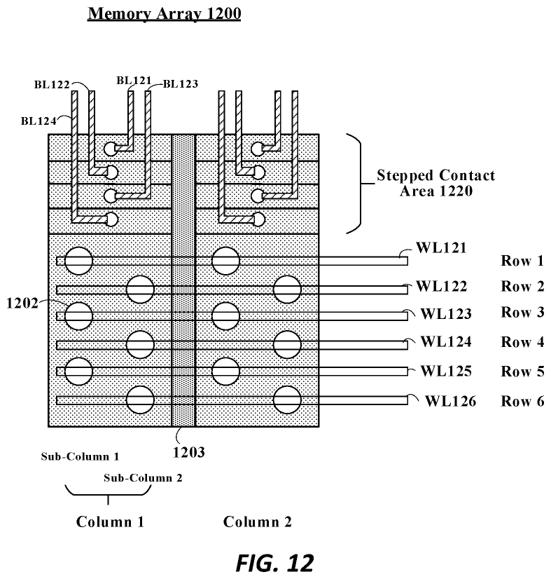

In some embodiments, an improved memory array may be obtained by combining the memory array structure e.g. as shown in FIG. 1 as described above with the spacing arrangement of the columnar gate structures e.g. as shown in FIG. 8. For example, the columnar gate structures of more than one column in FIG. 1 may be combined into one column according to the arrangement of adjacent sub-columns as shown in FIG. 8, thereby reducing the number of isolation parts 103 between columns and reducing the horizontal size of the array; such memory array structure may have the advantages of both the memory array 100 e.g. as shown in FIG. 1 and the memory array 800 e.g. as shown in FIG. 8, as will be described later in conjunction with FIGS. 12-15.

FIG. 12 shows a NOR memory according to at least one embodiment of the present disclosure, which may arrange vertical memory groups of two or more sub-columns in one column in the structure of FIG. 12, and the columnar gate structures 1202 of the vertical memory groups of at least two adjacent sub-columns are spaced in the column direction, thereby reducing the horizontal size of the memory array 1200. It should be noted that the arrangement structure of the vertical memory groups of the NOR memory shown in FIG. 12 may be implemented in conjunction with any embodiment shown in any of FIGS. 1-3 to further improve the density of the memory array. The vertical memory group structure of the NOR memory shown in FIG. 12 may also be independently implemented, and the present disclosure is not limited to this.

As shown in FIG. 12, in some embodiments, two or more adjacent sub-columns may be set in one column, and each sub-column may include two or more columnar gate structures 1202; wherein, the columnar gate structures 1202 of adjacent sub-columns are staggered in the row direction. Shown in FIG. 12 is an exemplary structure where one column includes two sub-columns; however, those skilled in the art may understand that this exemplary explanation is not a limitation to the embodiments of the present disclosure. On the basis of ensuring the possibility of technological implementation, any number of sub-columns may be arranged in one column, and for example, three sub-columns may be arranged in one column (not shown in the accompanying drawings of the specification).

In FIG. 12, the columnar gate structures 1202 of two sub-columns may be staggered and arranged in the same column. In some examples, the structure of the columnar gate structure 1202 corresponding to one vertical memory group may refer to the accompanying drawings of other embodiments of the present disclosure; for example, it may refer to that in any of FIGS. 1-3, or it may be any other shape of columnar gate structure. The columnar gate structure 1202 in FIG. 12 may be the same as the columnar gate structure 102 or 802 in other accompanying drawings; alternatively, the columnar gate structure 1202 in FIG. 12 may be any kind of columnar gate structure. Due to the fact that the size of the metal line (word line WL) connecting the columnar gate structures 1202 may be smaller than the size of the columnar gate structures 1202, the columnar gate structures 1202 in the two sub-columns may be connected to the corresponding word lines WL respectively, and the two word lines WL may extend side by side without any contact, as shown in FIG. 12. In some implementations, in order to arrange the memory array more closely, one columnar gate structure 1202 in the two sub-columns of FIG. 12 may have the same distance from each of its adjacent columnar gate structures 1202 in the column direction, and for example, this distance may be the minimum column spacing for the process or design. In some implementations, each columnar gate structure 1202 in the two sub-columns of FIG. 12 may have the same distance from each of its adjacent columnar gate structures 1202 in the row direction, and for example, this distance may be the minimum row spacing for the process or design. In the above embodiments, the minimum row spacing may be same as or different from the minimum column spacing.

The construction of the columnar gate structure 1202 shown in FIG. 12 may refer to the accompanying drawings of other embodiments of the present disclosure, such as the columnar gate structure 102 shown in FIGS. 1-3, or may be any other shape or structure of columnar gate structure. The specific structure and manufacturing process of the vertical memory groups in the memory array 1200 shown in FIG. 12 may also refer to the accompanying drawings of other embodiments of the present disclosure, for example, the content of the embodiments described in FIGS. 1-3, and will not be repeated here. Those skilled in the art understand that the present disclosure is not limited to the construction and manufacturing process of the aforementioned vertical memory group, and vertical memory groups with any other construction and manufacturing process may also be used. The write/read operations of the memory array 1200 shown in FIG. 12 may refer to the content of the write/read operations described earlier in conjunction with FIGS. 5-7, but other suitable write/read operations may also be used, and thus those operations will not be repeated here.

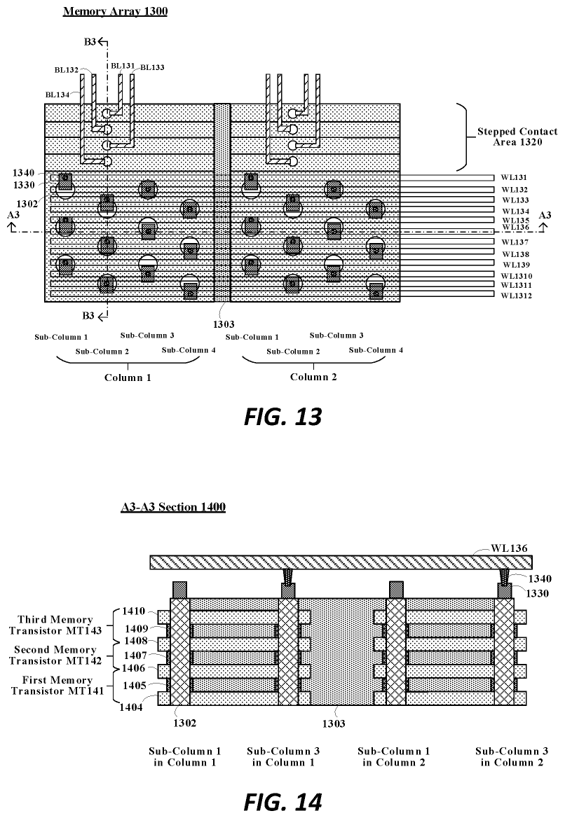

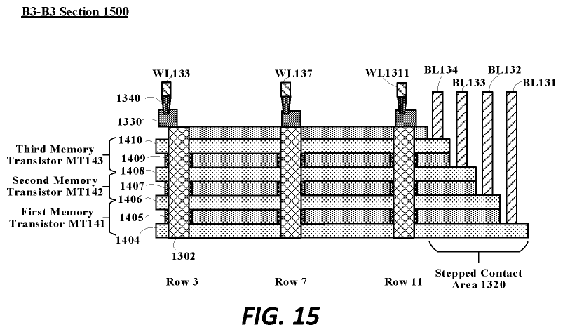

In addition, in some embodiments, the number of sub-columns in each column may be appropriately designed based on the ratio of the minimum size of the columnar gate structure to the minimum size of the word line WL, in order to better reduce the size of the entire memory array and improve integration density. For example, in some embodiments, the minimum size of the columnar gate structure may be exemplarily around 100 nm, where the minimum size may refer to the width of the columnar gate structure or the spacing between the columnar gate structures, and the width of the columnar gate structure may be the diameter of the circular hole. The minimum size of the metal line (word line WL) connecting the columnar gate structures may be exemplarily around 28 nm, which includes the width of the metal line and the spacing between adjacent metal lines. It can be seen that the ratio of the minimum size of the columnar gate structure to the minimum size of the word line WL in the above example may be around 4:1. In the above example, the minimum sizes of the columnar gate structure and the word line WL may determine that up to 4 sub-columns may be staggered in the same column, as shown in FIG. 13. The minimum size of the columnar gate structure and the minimum size of the word line WL mentioned above are only examples and are not limited to the disclosed embodiments.

FIG. 13 shows a schematic plan view of a memory array in a NOR memory according to another embodiment of the present disclosure, FIG. 14 shows a schematic cross-sectional view taken along the dashed line A3-A3 as shown in FIG. 13, and FIG. 15 shows a schematic cross-sectional view taken along the dashed line B3-B3 as shown in FIG. 13.

In FIG. 13, as an example, four sub-columns of columnar gate structures 1302 may be interleaved in the same column. Exemplarily, the structure of the columnar gate structure 1302 corresponding to one vertical memory group may refer to the accompanying drawings of other embodiments of the present disclosure. The construction of the columnar gate structure 1302 shown in FIG. 13 may refer to e.g. the columnar gate structure 102 shown in FIGS. 1-3, or may be any other shape or structure of columnar gate structure.

As shown in FIG. 13, due to the presence of two columnar gate structures 1302 placed side by side in the row direction in one column, it is difficult to stagger the connection by using the metal lines directly above the columnar gate structures 102 as the word lines WL as shown in FIGS. 1-3. Therefore, an additional metal layer may be added, as the word lines WL, above the metal layer in contact with and on the columnar gate structures 102 as shown in FIGS. 1-3. In some possible implementations, as shown in the plan view of FIG. 13 and the subsequent cross-sectional views of FIGS. 14 and 15, a contact metal 1330 is formed above each columnar gate structure 1302 to widen the connectable area of the columnar gate structure 1302, and then a via 1340 is formed on the contact metal 1330 to electrically contact it, and a metal line (word line WL) is formed on the upper layer of the via 1340 to electrically contact it. As needed, a connection structure similar to the contact metal 1330 and the via 1340 in FIGS. 13-15 may also be formed above the columnar gate structure 1202 shown in FIG. 12, which is not limited by the embodiments of the present disclosure.

In some possible implementations, in order to arrange the memory array more closely, each columnar gate structure 1302 in the four sub-columns of FIG. 13 may have the same distance (such as the minimum spacing) from each of its adjacent columnar gate structures 1302 in the column or row direction. That is to say, the columnar gate structures 1302 in each column may be arranged in the most compact hexagonal pattern, in order to further improve the array density.

Although only one contact for connecting a source/drain layer is shown in the stepped contact area 1320 in the accompanying drawings of this disclosure, this disclosure is not limited to this. In some possible implementations, for example, multiple contacts in contact with the same source/drain layer may be formed as needed and connected together with a metal line.

The aforementioned implementation methods of contacts and hexagonal pattern arrangement may be implemented independently or combined, and the embodiments of the present disclosure do not limit this.

In some possible implementations, as shown in the cross-sectional views of FIGS. 14 and 15, each vertical memory group in the memory array 1300 may include three vertically stacked memory transistors (i.e., the first to third memory transistors MT141-MT143), whose main difference from the structure of the vertical memory group shown in the cross-sectional views of FIGS. 2 and 3 is that, as shown in A3-A3 Section 1400 in FIG. 14, the columnar gate structures 1302 of multiple sub-columns in the same column may exist at the same horizontal position, and the source/drain layers of all sub-columns located at the same stack layer are continuous; in addition, as mentioned earlier, the connection structure with the contact metal 1330 and the via 1340 is added above the columnar gate structure 1302 to connect to the word line WL. Other specific structures and manufacturing processes of the vertical memory group shown in the cross-sectional views of FIGS. 14 and 15 may refer to those in the previous embodiments described in combination with FIGS. 2 and 3, and will not be further elaborated here. Those skilled in the art understand that the present disclosure is not limited to the construction and manufacturing process of the vertical memory group mentioned above, and vertical memory groups with any other construction and manufacturing process may also be used.

Please note that in order to make the illustrations clear and highlight the key points, there are blank areas left between many components in the cross-sectional views of FIGS. 14 and 15, which does not necessarily limit these areas to be empty. In some implementations, in actual devices, all or part of these blank areas may be filled with electrical insulation materials to isolate and support these components.

The write/read operations of the memory array 1300 shown in FIG. 13 may refer to the content of the write/read operations described earlier in conjunction with FIGS. 5-7, but other suitable write/read operations may also be used, and thus those operations will not be repeated here.

Below are a few specific examples to illustrate.

In some possible implementations, as shown in FIGS. 1-3, the NOR memory array 100 includes multiple vertical memory groups 101 arranged in n rows×m columns on the horizontal plane; wherein the vertical memory groups 101 in one column may be arranged as shown in FIG. 12, where one column includes two sub-columns. The memory array 100 in FIGS. 1-3 is also regarded as the memory array 1200 in FIG. 12.

In some possible implementations, as shown in FIGS. 1-3, the NOR memory array 100 includes multiple vertical memory groups 101 arranged in n rows×m columns on the horizontal plane; wherein the vertical memory groups 101 in one column may be arranged as shown in FIG. 13, or in a similar manner (such as including 3 sub-columns in one column). The memory array 100 in FIGS. 1-3 is also regarded as the memory array 1300 in FIG. 13.

In some possible implementations, in the memory array 1200 shown in FIG. 12, the vertical memory groups in one column may be arranged as shown in FIG. 12, with two sub-columns in one column. The columnar gate structure 1202 may adopt the structure of columnar gate structure 102 as shown in any one of FIGS. 1-3, or may be other kinds of columnar gate structure 1202.

In some possible implementations, in the memory array 1300 shown in FIG. 13, the vertical memory groups in one column may be arranged as shown in FIG. 13, with four sub-columns in one column. The columnar gate structure 1302 may adopt the structure of columnar gate structure 102 as shown in any one of FIGS. 1-3, or may be other kinds of columnar gate structure 1302.

In addition, the above-described NOR memory arrays and corresponding NOR memories according to the embodiments of the present disclosure may be applied to various electronic devices with storage needs, such as smartphones and their peripheral electronic devices (such as Bluetooth headphones and wearable devices and the like), electronic devices using the Internet of Things, in-vehicle electronic devices and the like.

Those skilled in the art may understand that appropriate modifications can be made to various above-described circuit structures of the present disclosure as needed, all of which are within the scope of protection of the present disclosure.

Various embodiments of the present disclosure have been described above, and the foregoing descriptions are exemplary, not exhaustive, and not limiting of the disclosed embodiments. Numerous modifications and variations will be apparent to those of ordinary skill in the art without departing from the scope and spirit of the described embodiments. The terminology used herein was chosen to best explain the principles of the various embodiments, the practical application or improvement over the technology in the marketplace, or to enable others of ordinary skill in the art to understand the various embodiments disclosed herein.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A NOR memory array comprising:
multiple vertical memory groups arranged in n rows and m columns on a horizontal plane, wherein one vertical memory group includes at least h vertically stacked memory transistors, where n, m, and h are natural numbers greater than 1,
wherein, the memory transistors in the one vertical memory group share a vertically extended columnar gate structure,
part or all of the columnar gate structures of vertical memory groups in a same row are connected to a same word line,
part or all of the memory transistors located at a same stack layer in vertical memory groups in a same column are connected to a same bit line, and
an isolation part, for isolating active areas and bit lines of the memory transistors in the adjacent columns, is arranged between adjacent columns of the vertical memory groups.

2. The NOR memory array according to claim 1, wherein,
the one vertical memory group comprises h+1 source/drain layers and h channel layers alternately stacked in a vertical direction, wherein each channel layer and two source/drain layers contacted therewith in the vertical direction construct an active area of one memory transistor, wherein two adjacent memory transistors in the vertical direction share a common source/drain layer, and the h+1 source/drain layers are respectively connected to h+1 metal lines that construct the respective bit lines or source lines of the h memory transistors.

3. The NOR memory array according to claim 2, wherein,
the vertical memory groups in the same column share the h+1 source/drain layers, and contacts for respectively connecting to the h+1 metal lines that construct the respective bit lines or source lines of the h memory transistors are respectively provided at ends of the source/drain layers of each column.

4. The NOR memory array according to claim 1, wherein,
at least one column of the vertical memory groups includes i sub-columns of the vertical memory groups, where i is a natural number greater than 1; wherein the columnar gate structures of at least two adjacent sub-columns of the vertical memory groups are spaced in the column direction.

5. The NOR memory array according to claim 4, wherein,
each columnar gate structure in the i sub-columns has a same distance from each of the columnar gate structures adjacent to it in the column direction;
or,
each columnar gate structure in the i sub-columns has a same distance from each of the columnar gate structures adjacent to it in the row direction;
or,
each columnar gate structure in the i sub-columns has a same distance from each of the columnar gate structures adjacent to it in the row or column direction.

6. A NOR memory array comprising:
multiple vertical memory groups arranged in n rows and m columns on a horizontal plane, wherein one vertical memory group includes at least h vertically stacked memory transistors, where n, m, and h are natural numbers greater than 1,
wherein, the memory transistors in the one vertical memory group share a vertically extended columnar gate structure,
part or all of the columnar gate structures of vertical memory groups in a same row are connected to a same word line,
part or all of the memory transistors located at a same stack layer in vertical memory groups in a same column are connected to a same bit line, and
wherein, at least one column of the vertical memory groups includes i sub-columns of the vertical memory groups, where i is a natural number greater than 1; wherein the columnar gate structures of at least two adjacent sub-columns of the vertical memory groups are spaced in the column direction.

7. The NOR memory array according to claim 6, wherein,
an isolation part, for isolating active areas and bit lines of the memory transistors in the adjacent columns, is arranged between adjacent columns of the vertical memory groups.

8. A NOR memory, comprising a NOR memory array according to claim 1, and a write operation part,
wherein, the write operation part is configured to apply a gate write voltage to a columnar gate structure of a vertical memory group to be written, and to apply a source voltage or a bit line write voltage to bit lines and source lines of the vertical memory group to be written, respectively, so that there is only a write voltage difference between two source/drain layers of a memory transistor in which data “0” is to be written.

9. A NOR memory, comprising a NOR memory array according to claim 6, and a write operation part,
wherein, the write operation part is configured to apply a gate write voltage to a columnar gate structure of a vertical memory group to be written, and to apply a source voltage or a bit line write voltage to bit lines and source lines of the vertical memory group to be written, respectively, so that there is only a write voltage difference between two source/drain layers of a memory transistor in which data “0” is to be written.

10. A NOR memory, comprising a NOR memory array according to claim 1, and a read operation part,
wherein, the read operation part is configured to apply a gate read voltage to a columnar gate structure of a vertical memory group to be read, and to apply a source voltage or a bit line read voltage to bit lines and source lines of the vertical memory group to be read, respectively, so that there is only a read voltage difference between two source/drain layers of one memory transistor to be read therein.

11. A NOR memory, comprising a NOR memory array according to claim 6, and a read operation part,
wherein, the read operation part is configured to apply a gate read voltage to a columnar gate structure of a vertical memory group to be read, and to apply a source voltage or a bit line read voltage to bit lines and source lines of the vertical memory group to be read, respectively, so that there is only a read voltage difference between two source/drain layers of one memory transistor to be read therein.

12. An electronic device comprising a NOR memory array according to claim 1.

13. An electronic device comprising a NOR memory array according to claim 6.

14. An electronic device comprising a NOR memory according to claim 8.

15. An electronic device comprising a NOR memory according to claim 9.

16. An electronic device comprising a NOR memory according to claim 10.

17. An electronic device comprising a NOR memory according to claim 11.
